(19) United States
(12) Patent Application Publication
(10) Pub. No.: US 2005/0242411 A1
(43) Pub. Date: Nov. 3, 2005

(54) [SUPERJUNCTION SCHOTTKY DEVICE AND FABRICATION THEREOF]

(76) Inventor: Hsuan Tso, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/709,334

(22) Filed: Apr. 29, 2004

(51) Int. Cl. H01L 29/812

(52) U.S. Cl. 257/480; 257/483; 257/484; 257/481

(57) ABSTRACT

A superjunction Schottky device is described. The Schottky device includes a back metal layer, a semiconductor substrate of a first conductivity type, superjunction cells on the substrate, a lightly-doped JBS (Junction Barrier Schottky) region of the first conductivity type on each superjunction cell, and a front conductor layer. The superjunction cells include numerous charge-balanced junctions that extend substantially vertically, and the front conductor layer is disposed contacting with the JBS region to form a Schottky contact.

### BACKGROUND OF INVENTION

1. Field of the Invention

The present invention relates to a semiconductor device and a method for fabricating the same. More particularly, the present invention relates to a superjunction Schottky device that is suitably used as a power device, and a method for fabricating the same.

2. Description of the Related Art

Schottky diode is a rectifying device essentially consisting of a lightly doped semiconductor layer and a metallic layer thereon, wherein the contact between the lightly doped semiconductor layer and the metallic layer is called a “Schottky contact”. The doping concentration of the lightly doped semiconductor layer is quite low for high voltage application, so that the difference between the work function of the metal and that of the semiconductor is quite large, resulting in low leakage current (Ir) between anode and cathode at reverse bias. Therefore, Schottky diode is suitably used as a high-voltage rectifying device in power circuits. However, the forward bias drop (Vf) is adversely increased because the semiconductor layer having low doping concentration is thick. Moreover, when a high reverse bias exceeding the breakdown voltage of the device, such as, a transient reverse surge, is applied to the device, breakdown readily occurs at the Schottky contact causing a large current that will damage the Schottky contact. Consequently, there is a need to improve the Vf for high voltage application.

On the other hand, U.S. Pat. No. 6,081,009 and U.S. Pat. No. 6,346,464 and U.S. patent application Pub. No. 20020171093 disclosed superjunction MOSFET structures that allow ON-resistance of the power devices to be reduced without lowering the breakdown voltage. The superjunction structure essentially includes vertical P-doped layers and N-doped layers that are arranged alternately, while the breakdown voltage of the device is stabilized by the junction depletion regions extending vertically in the superjunction structure. However, the alternate PN superjunction is suitable for MOSFET but not suitable for Schottky rectifier, which requires lightly doped region contacting with metal system for low Ir. Therefore, superjunction structures different from those applied to MOSFET are necessary.

### SUMMARY OF INVENTION

In view of the foregoing, this invention provides a superjunction Schottky device capable of protecting the Schottky contact once electrical breakdown occurs.

This invention also provides a method for fabricating a superjunction Schottky device according to this invention.

The superjunction Schottky device of this invention includes a back metal layer, a heavily doped semiconductor substrate of a first conductivity type on the back metal layer, superjunction cells on the substrate, a conventional JBS (Junction Barrier Schottky) region on the top of each superjunction cell, and a front conductor layer contacting with the JBS region. The superjunction cells include numerous charge-balanced PNN

For different manufacturing methods, in some embodiments of the superjunction Schottky device of this invention, two superjunction cells are separated by an isolation structure formed by trench etch and refilling with isolating material(s). In other embodiments, the superjunction cells are formed by multiple deposition and ion implantation method and are arranged adjacent to each other, so that more conducting paths are formed lowering the resistance of the Schottky device.

The method for fabricating a superjunction Schottky device of this invention is described as follows. A heavily doped semiconductor substrate of a first conductivity type is provided, and then superjunction cells are formed on a front side of the substrate. A lightly-doped JBS region of the first conductivity type is formed on each superjunction cell, and a front conductor layer is formed over the substrate contacting with the JBS region to form a Schottky contact. A back metal layer is then formed on the back side of the substrate.

In some embodiments where isolation structures are formed, the superjunction cells can be formed by, for example, forming a lightly doped semiconductor layer of the first conductivity type, forming trenches in the semiconductor layer to define active regions, and then forming charged-balanced junctions in sidewalls of the active regions with tilt ion implantation. In other embodiments where superjunction cells are formed adjacent to each other, the superjunction cells can be formed using multiple deposition and ion implantation method. In each deposition step, a thin lightly doped semiconductor sub-layer of the first conductivity type is formed. In the subsequent ion implantation step, numerous first layers of the first conductivity type and second layers of the second conductivity type are formed in the thin semiconductor sub-layer just formed to form multiple junctions. The first and second layers in each semiconductor sub-layer are aligned with those in the previous semiconductor sub-layer, so that the height of the first and second layers is increased step by step. The multiple deposition/implantation method is performed until a required height of the first and second layers is obtained. The former method for forming the superjunction cells is cost effective, but the latter method provides more conducting paths to lower the resistance of the Schottky device.

In the superjunction Schottky device of this invention, the superjunction cells will reach a breakdown point prior to the Schottky contact between the JBS region and the conductor layer. Therefore, when an overly high reverse voltage is applied to the Schottky device, the superjunction cells share most of the voltage load and thereby sustain high voltage and protect the Schottky contact.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a superjunction Schottky device according to a first embodiment of this invention in a cross-sectional view.

FIG. 2 illustrates a superjunction Schottky device according to a second embodiment of this invention in a cross-sectional view.

FIG. 3 illustrates a superjunction Schottky device according to a third embodiment of this invention in a cross-sectional view.

FIG. 4 illustrates a superjunction Schottky device according to a fourth embodiment of this invention in a cross-sectional view.

FIG. 5 illustrates a superjunction Schottky device according to a fifth embodiment of this invention in a cross-sectional view.

FIG. 6 illustrates a superjunction Schottky device according to a sixth embodiment of this invention in a cross-sectional view.

FIGS. 7A-7F illustrates a process flow of fabricating a superjunction Schottky device according to the first embodiment of this invention in a cross-sectional view.

FIGS. 8A-8F illustrates a process flow of fabricating a superjunction Schottky device according to the second embodiment of this invention in a cross-sectional view.

FIGS. 9A-9C illustrates a process flow of fabricating a superjunction Schottky device according to the third embodiment of this invention in a cross-sectional view.

FIGS. 10A-10D illustrates a process flow of fabricating a superjunction Schottky device according to the fourth embodiment of this invention in a cross-sectional view.

### DETAILED DESCRIPTION

In the following embodiments of this invention, similar parts are labeled with similar reference numbers, while some parts without variation are explained only once on their appearance. For example, 122, 222, . . . , 622 are used to label the superjunction cells in the first to sixth embodiments, respectively, and the blocking layer (160, 260, . . . , 660) on the edge termination is explained only once.

<Structure of Superjunction Schottky Device>

### First Embodiment

FIG. 1 illustrates a superjunction Schottky device according to the first embodiment of this invention in a cross-sectional view. The Schottky device includes an N⁺⁺-substrate 100, a back metal layer 110 on the back side of the substrate 100, multiple active regions 120 and isolation layers 130, lightly N-doped edge termination 140 on the peripheral portion of the substrate 100, and a front conductor layer 150 on the active regions 120 and the isolation layers 130. The substrate 100 may be a heavily N-doped single-crystal silicon substrate, and the doping concentration of the substrate 100 is, for example, 3.5×10¹⁹/cm³.

The active regions 120 and the isolation layers 130 are arranged alternately, wherein each active region 120 includes a superjunction cell 122, a lightly N-doped junction barrier Schottky (JBS) region 124 on the superjunction cell 122, and a P-type guard ring 126 at the periphery of the JBS region 124. For a 100V Schottky device, the doping concentration of the JBS region 124 is about 2.5×10¹⁵/cm³. For a 600V Schottky device, the doping concentration of the JBS region 124 is lowered by approximately an order of magnitude (˜3.0×10¹⁴/cm³) to further increase the work function difference between the JBS region 124 and the front conductor layer 150.

Referring to FIG. 1 again, each superjunction cell 122 includes two vertical P-doped layers 1224, two vertical N-doped layers 1222 between the two P-doped layers 1224 and a lightly N-doped layer between the two N-doped layers 1222. The lightly N-doped layer is contiguous with the lightly N-doped JBS region 124. Within each superjunction cell 122, the total number of the P-dopant is equal to that of the N-dopant to make charge balance, so that the superjunction cell 122 is fully depleted to achieve optimal performance. The P/N-doping concentration in the superjunction cells 122 is significantly higher relative to that in the JBS region 124, typically 1×10¹⁵/cm³ to 1×10¹⁷/cm³. Each isolation structure 130 includes a material selected from the group consisting of doped and undoped oxide, nitride and polysilicon, and combinations thereof. In this embodiment, each isolation structure 130 includes a thin insulating layer 134, such as, a thin nitride or oxide layer, contacting with the active regions 120 and the substrate 100, and a polysilicon layer 132 filling up the space between two active regions 120.

The P-type guard ring 126 is disposed at the periphery of the JBS region 124over the two P-doped layers 1224 and the two N-doped layers 1222. The P-type guard ring 126 is for reducing the surface current conduction (leakage) and the resulting high edge electric field, and also serves to protect the Schottky contact area of the JBS region 124 from transient reverse surges. The doping concentration of P-type guard ring 126 is quite high, approximately higher than 1×10¹⁹/cm³, so that the contact between the P-type guard ring 126 and the front conductor layer 150 is considered to be ohmic.

The edge termination 140 is mainly for preventing reverse and/or forward current conduction outside of the main die construction, while the design of the edge termination 140 can vary widely. For example, P-type guard rings 142 may also be formed in the edge termination 140. The front conductor layer 150 may be a metal layer, or a composite layer including a metal silicide layer 152 that forms Schottky contacts with the JBS regions 124 and a metal layer 154 on the metal silicide layer 152. The metal in the metal silicide layer 152 is selected from the group consisting of Au, Pt, Ni, Ti, W, Co, Rh, Pd, Zr, Ta, Cr, Mo and alloys of the above metals with various weight ratios. The material of the metal layer 154 can be Al, Al/Si alloy, Al/Si/Cu alloy, Mo/Al alloy, Al/Ni/Au alloy or Ti/Ni/Ag alloy. In addition, a blocking layer 160 like a silicon oxide layer is disposed on the edge termination 140 serving as a mask in the silicide process, which will be explained latter.

### Second Embodiment

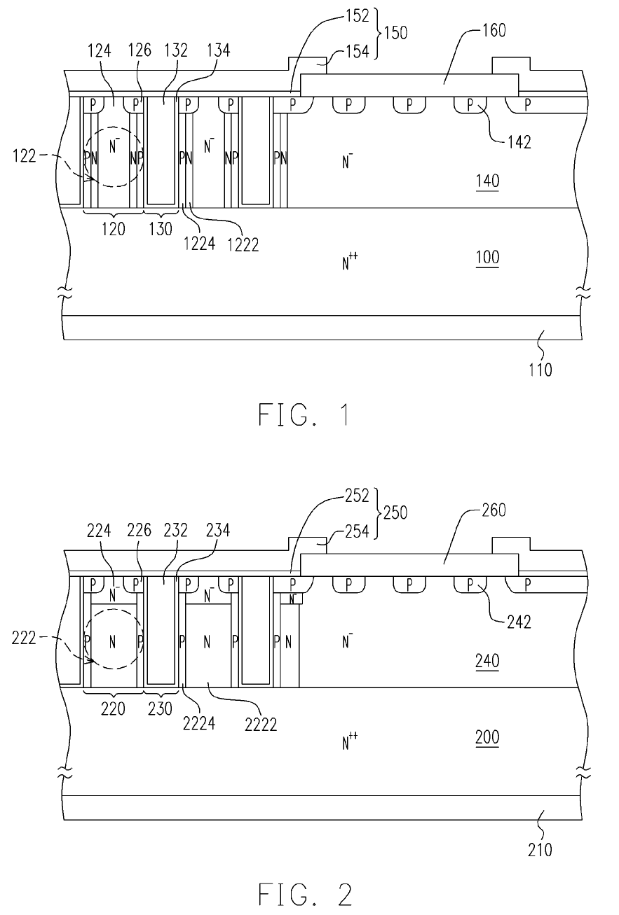

FIG. 2 illustrates a superjunction Schottky device according to the second embodiment of this invention in a cross-sectional view. The Schottky device includes an N⁺⁺-substrate 200, a back metal layer 210, multiple active regions 220 and isolation layers 230, lightly N-doped edge termination 240 and a front conductor layer 250 that are arranged as in the first embodiment (FIG. 1). In this embodiment, each active region 220 includes a superjunction cell 222, a lightly N-doped JBS region 224 on the superjunction cell 222, and a P-type guard ring 226 at the periphery of the JBS region 224.

The superjunction cell 222 includes two P-doped layers 2224 and an N-doped layers 2222 between the two P-doped layers 2224. The N-doped layer 2222 is located under the lightly N-doped JBS region 224, and P-type guard ring 226 over the two P-doped layers 2224 and a portion of the N-doped layer 2222.

### Third Embodiment

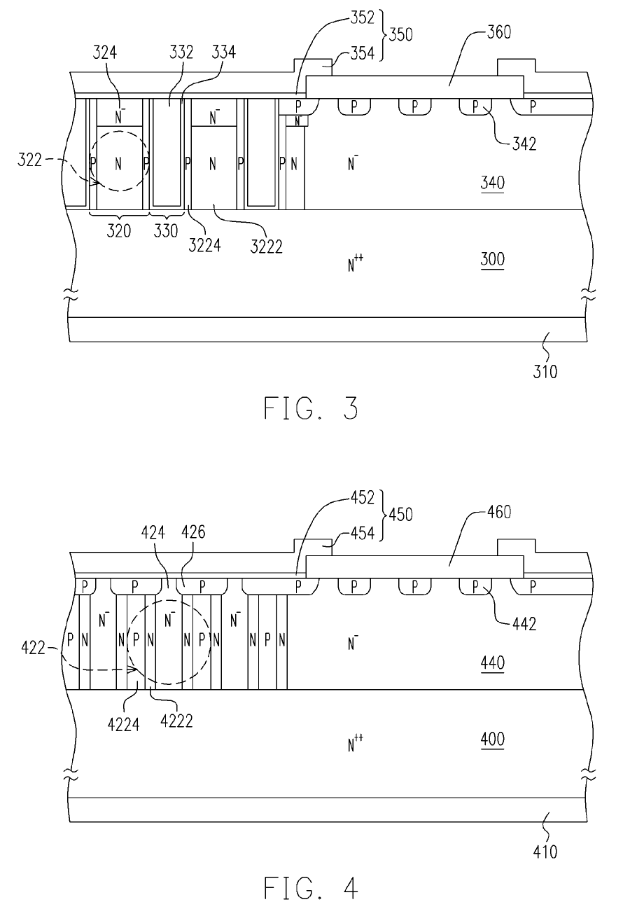

FIG. 3 illustrates a superjunction Schottky device according to the third embodiment of this invention in a cross-sectional view. The structures and the arrangement of the substrate 300, the back metal layer 310, the active regions 320, the isolation structures 330, the edge termination 340 and the front conductor layer 350 are similar to those mentioned in the second embodiment. This embodiment differs from the second embodiment in that no P-typed guard ring is disposed in the active region, and only the edge termination 340 is disposed with P-type guard rings 342 therein.

### Fourth Embodiment

FIG. 4 illustrates a superjunction Schottky device according to the fourth embodiment of this invention in a cross-sectional view. The Schottky device includes an N⁺⁺-substrate 400, a back metal layer 410 on the back side of the substrate 400, multiple superjunction cells 422 on the substrate 400, a lightly N-doped JBS region 424 on each superjunction cell 422, a P-doped guard ring 426 at the periphery of each JBS region 424, a lightly N-doped edge termination 440 on the peripheral portion of the substrate 400, and a front conductor layer 450 contacting with the JBS regions 424. The superjunction cells 422 are arranged adjacent to each other, wherein each superjunction cell 422 includes two P-doped layers 4224, two N-doped layers 4222 between the two P-doped layers 4224 and a lightly N-doped layer between the two N-doped layers 4222. The lightly N-doped layer is contiguous with the JBS region 424, and the P-doped guard ring 426 is located over the P-doped layers 4224 and the N-doped layers 4222 and under the front conductor layer 450.

As compared with the Schottky device in the first embodiment (FIG. 1) that has the same superjunction cell structure (P/N/N/N/P), the number of superjunction cells of the Schottky device in the fourth embodiment is larger because no isolation structure is formed therein. Therefore, more conductive paths can be provided to reduce the resistance of the Schottky device.

### Fifth Embodiment

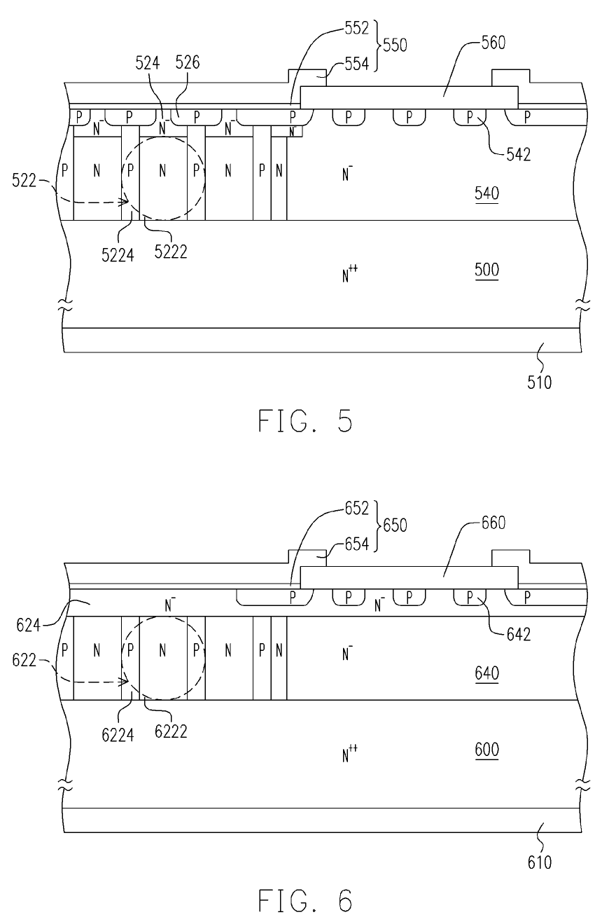

FIG. 5 illustrates a superjunction Schottky device according to the fifth embodiment of this invention in a cross-sectional view. The Schottky device includes an N⁺⁺-substrate 500, a back metal layer 510, superjunction cells 522, lightly N-doped JBS regions 524, P-doped guard ring 526, a lightly N-doped edge termination 540 and a front conductor layer 550 in an arrangement similar to that mentioned in the fourth embodiment (FIG. 4). In this embodiment, each superjunction cell 522 includes two P-doped layers 5224 and an N-doped layer 5222 between the two P-doped layers 5224. The N-doped layer 5222 is under the JBS region 524, and the two P-doped layers 5224 extend upward to the periphery of the JBS region 524. The P-doped guard ring 526 is disposed at the periphery of the JBS region 524 over the two P-doped layers 5224.

### Sixth Embodiment

FIG. 6 illustrates a superjunction Schottky device according to the sixth embodiment of this invention in a cross-sectional view. The structures and the arrangement of the N⁺⁺-substrate 600, the back metal layer 610, the superjunction cells 622, the edge termination 640 and the front conductor layer 650 are similar to those mentioned in the fifth embodiment. However, in this embodiment, the JBS region 624 is a continuous N-doped layer over all superjunction cells 622, and no P-type guard ring is form in the active region. Only the edge termination 640 is disposed with P-type guard rings 642 therein.

As compared with the Schottky device in the second or third embodiment (FIG. 2 or 3) that has the same superjunction cell structure (P/N/P), the number of superjunction cells of the Schottky device in the fifth or sixth embodiment is larger because no isolation structure is formed therein. Therefore, more conductive paths can be provided to reduce the resistance of the Schottky device.

<Fabrication of Superjunction Schottky Device>

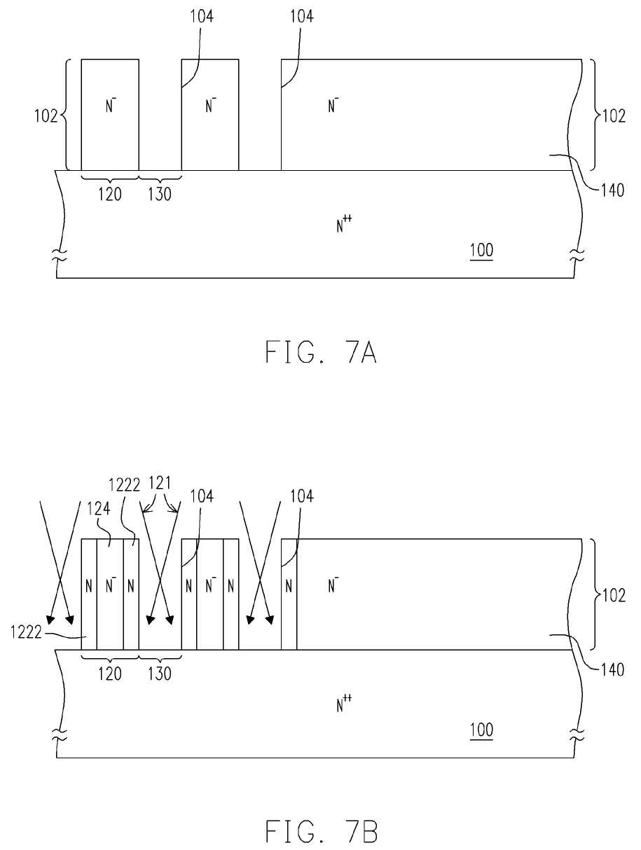

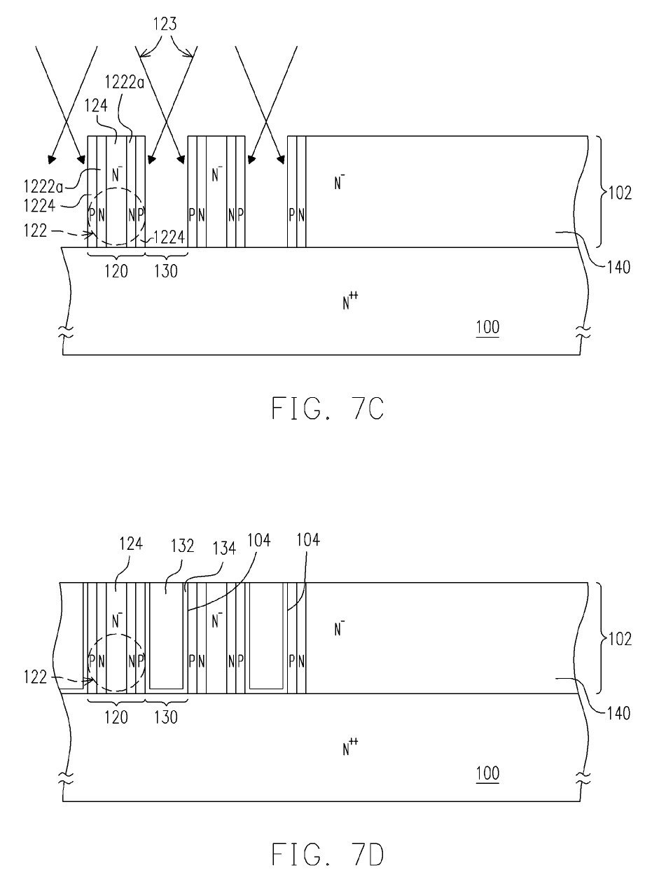

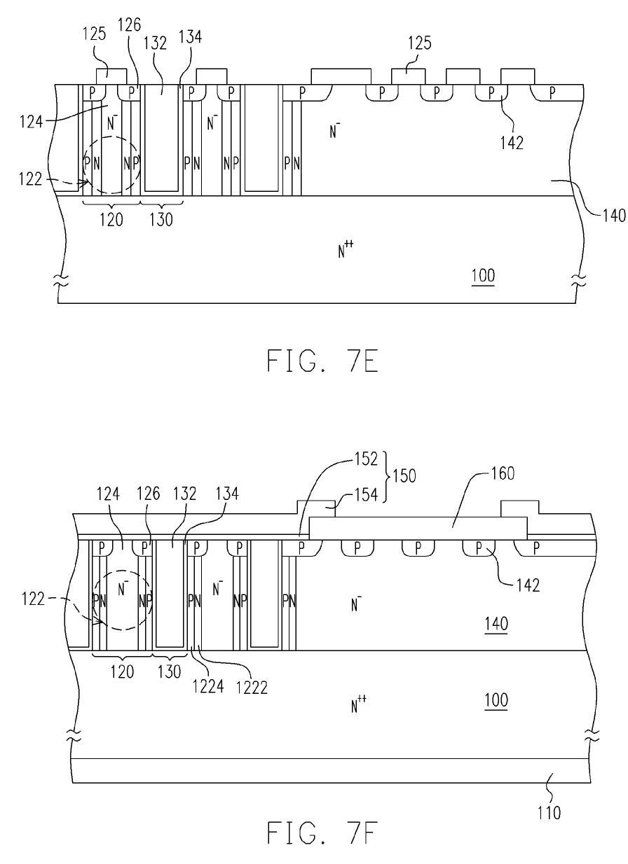

FIGS. 7A-7F illustrates a process flow of fabricating a superjunction Schottky device according to the first embodiment of this invention in a cross-sectional view.

Referring to FIG. 7A, an N⁺⁺-substrate 100 is provided. A semiconductor layer 102, such as, an epitaxial silicon layer, is formed on the substrate 100. Then, multiple trenches 104 are formed in the substrate 100 to define active regions 120 and the regions of isolation structures 130 that are arranged alternately, and an edge termination 140 on the periphery portion of the substrate 100.

Referring to FIG. 7B, tilt ion implantation 121 of N-type is performed to form two N-doped layers 1222 in two sidewalls of each active region 120. The tilt ion implantation 121 is divided into two steps, wherein one is conducted in a tilt angle of 2 to 25 degrees and the other in a tilt angle of −2 to −25 degrees.

Referring to FIG. 7C, an annealing process is performed to diffuse the N-type dopant in the N-doped layers 1222, so that the thickness of the N-doped layers 1222 is increased. Then, another tilt ion implantation 123 of P-type is performed to form two P-doped layers 1224 in the outward sidewall of each N-doped layer 1222, while the remaining portion of the N-doped layer 1222 is labeled with “1222a”. The tilt ion implantation 123 is also divided into two steps, wherein one is conducted in a tilt angle of 2 to 25 degrees and the other in a tilt angle of 2 to 25 degrees. Another annealing process is then performed diffusing the P-type dopant in the P-doped layers 1224, thereby completing the fabrication of superjunction cells 122. The N-doped region in the middle of each active region 120 not containing the dopants implanted in the above two tilt implantation processes serves as a JBS region 124. Within each superjunction cell 122, the total number of the P-dopant and that of the N-dopant are made equal to make charge balance, so that the superjunction cell 122 is fully depleted to achieve optimal performance.

Referring to FIG. 7D, the trenches 104 are filled with a refill material to form isolation structures 130. The refill material is selected from the group consisting of doped and undoped oxide, nitride and polysilicon, and combinations thereof. In the illustrated case, each isolation structure 130 includes a thin insulating layer, such as, a thin nitride or oxide layer 134, on the surface of the corresponding trench 104, and a polysilicon layer 132 filling up the trench 104.

Referring to FIG. 7E, a guard-ring mask layer 125 is formed over the JBS region 104 in each active region 120 and over the edge termination 140. Then, a P-type guard ring 126 is formed in the top portion of each active region 120 at the periphery of the JBS region 124, and multiple P-type guard rings 142 are also formed in the top portion of the edge termination 140.

Referring to FIG. 7F, the guard-ring mask layer 125 is removed, and then a blocking layer 160, such as, a silicon oxide layer, is formed on the edge termination 140 exposing the active regions 120 and the isolation structures 130. A front conductor layer 150 is then formed over the substrate 100 contacting with the JBS regions 124 and the P-type guard rings 126. The front conductor layer 150 may be a metal layer, or a composite layer formed by sequentially forming a metal silicide layer 152 that contacts with the JBS regions 124 and the P-type guard rings 126 using the blocking layer 160 as a mask, and then forming a metal layer 154 on the metal silicide layer 152. Thereafter, a back metal layer 110 is formed on the back side of the substrate 100.

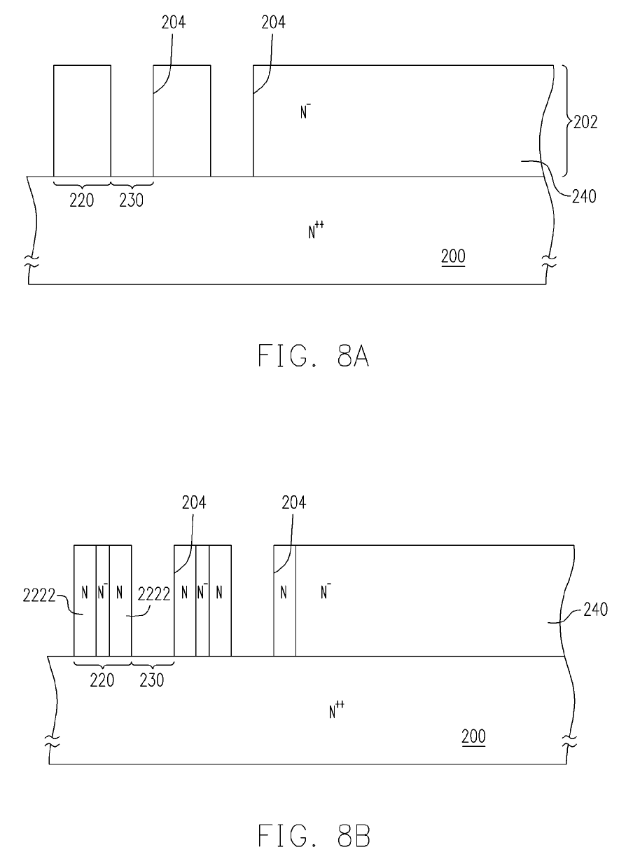

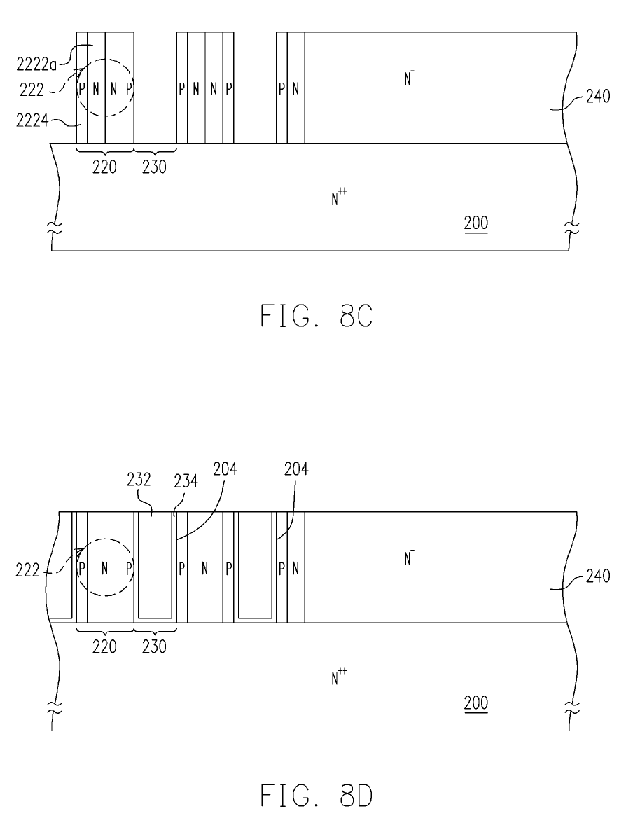

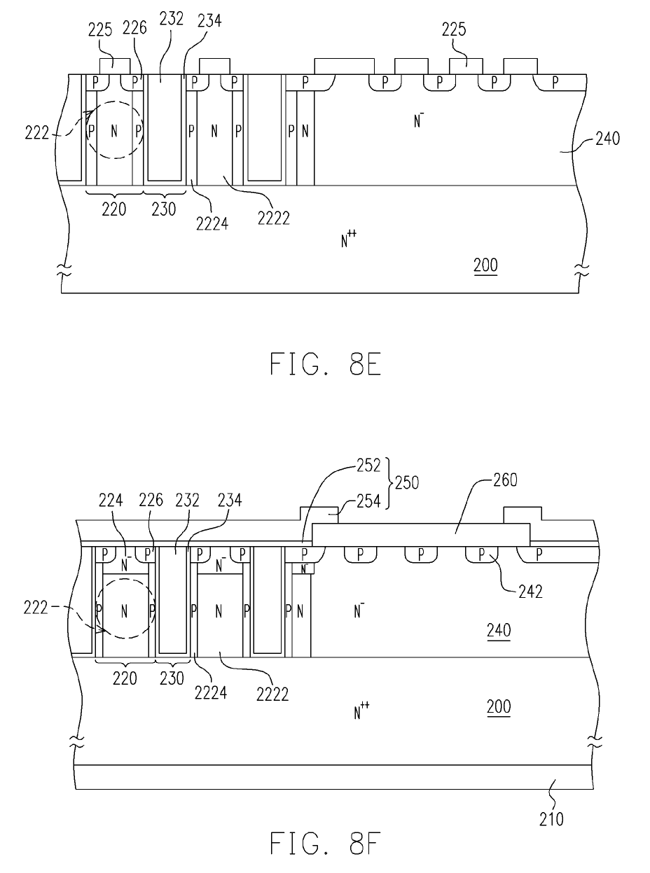

FIGS. 8A-8F illustrates a process flow of fabricating a superjunction Schottky device according to the second embodiment of this invention in a cross-sectional view.

Referring to FIG. 8A, an N⁺⁺-substrate 200 is provided, and an N-doped semiconductor layer 202 is formed on the substrate 200. Then, multiple trenches 204 are formed in the substrate 200 to define active regions 220 and isolation regions 230 that are arranged alternately, and an edge termination 240 on the periphery portion of the substrate 200.

Referring to FIG. 8B, two N-doped layers 2222 are formed in two sidewalls of each active region 220 with tilt ion implantation as mentioned above, and then an annealing process is performed to diffuse the N-type dopant in the two N-doped layers 2222, thereby increasing the thickness of the two N-doped layers 2222.

Referring to FIG. 8C, a P-doped layer 2224 is formed in the outward sidewall of each N-doped layer 2222 with tilt ion implantation as mentioned above, and another annealing process is performed to diffuse the P-type dopant in the P-doped layers 2224 and the N-type dopant in the N-doped layers 2222, thereby completing the fabrication of superjunction cells 222. In this case, the annealing conditions are controlled so that the two N-doped layers 2222 in each active region 220 are merged into one N-doped layer 2222 through dopant diffusion.

Referring to FIG. 8D, the trenches 204 are filled with a refill material to form isolation structures 230. Each isolation structure 230 may include a thin insulating layer 234 and a polysilicon layer 232, as mentioned above.

Referring to FIG. 8E, a guard-ring mask layer 225 is formed over each active region 220 and the edge termination 240. Then, a P-type guard ring 226 is formed in the top portion of each active region 220 over the two P-doped layers 2224 and a portion of the N-doped layer 2222.

Referring to FIG. 8F, the guard-ring mask layer 225 is removed, and then a blocking layer 260 is formed on the edge termination 240 exposing the active regions 220 and the isolation structures 230. A lightly N-doped JBS region 124 is then formed in the top portion of each N-doped layer 2222 by implanting a dopant of the opposite conductivity type, i.e., a P-type dopant, to the whole substrate 200 using the insulating 260 as a mask. A front conductor layer 250 is then formed over the substrate 200 contacting with the JBS regions 224 and the P-type guard ring 226. Thereafter, a back metal layer 210 is formed on the back side of the substrate 200.

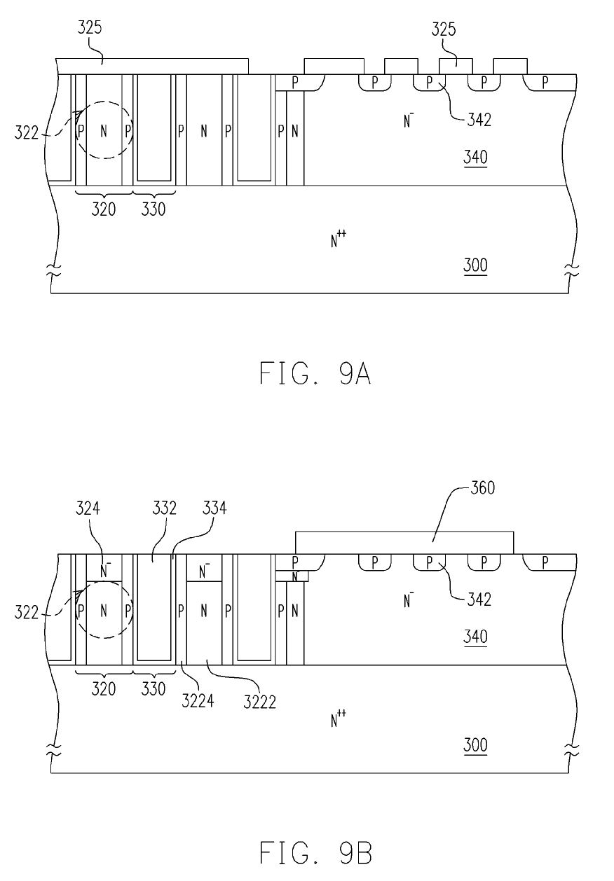

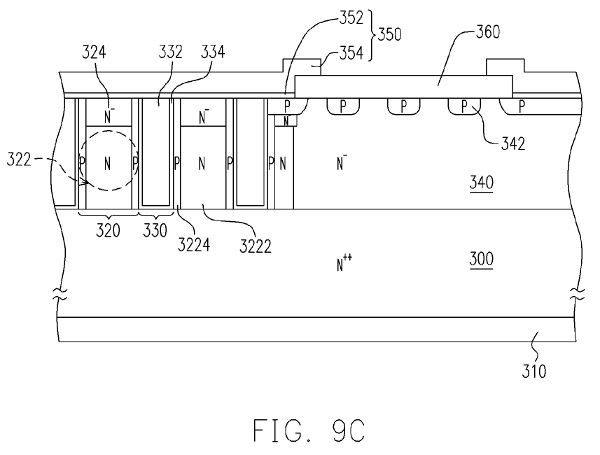

FIGS. 9A-9C illustrates a latter part of a process flow of fabricating a superjunction Schottky device according to the third embodiment of this invention in a cross-sectional view. The former part of the process flow can be the same as those illustrated in FIGS. 8A-8D.

Referring to FIG. 9A, a guard-ring mask layer 325 is formed covering all active regions 320 but exposing portions of the edge termination 340. Then, P-type guard rings 342 are formed in the top portion of the edge termination 340.

Referring to FIG. 9B, the guard-ring mask layer 325 is removed, and then a block insulating layer 360 is formed on the edge termination 340 exposing the active regions 320 and the isolation structures 330. A lightly N-doped JBS region 324 is then formed in the top portion of each N-doped layer 3222 between the P-doped layers 3224 by implanting a dopant of the opposite conductivity type, i.e., a P-type dopant, to the whole substrate 300 using the blocking 360 as a mask.

Referring to FIG. 9C, a front conductor layer 350 is then formed over the substrate 300 contacting with the JBS regions 324. Thereafter, a back metal layer 310 is formed on the back side of the substrate 300.

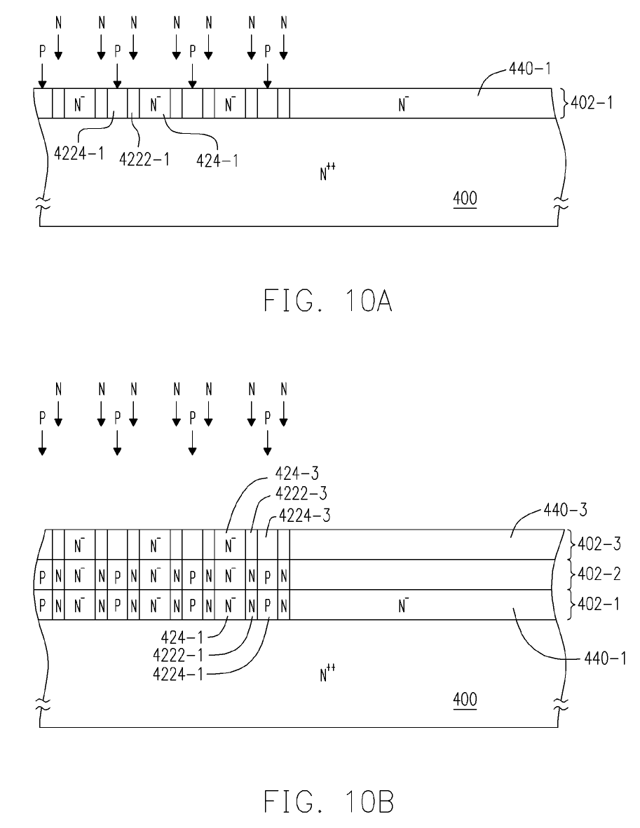

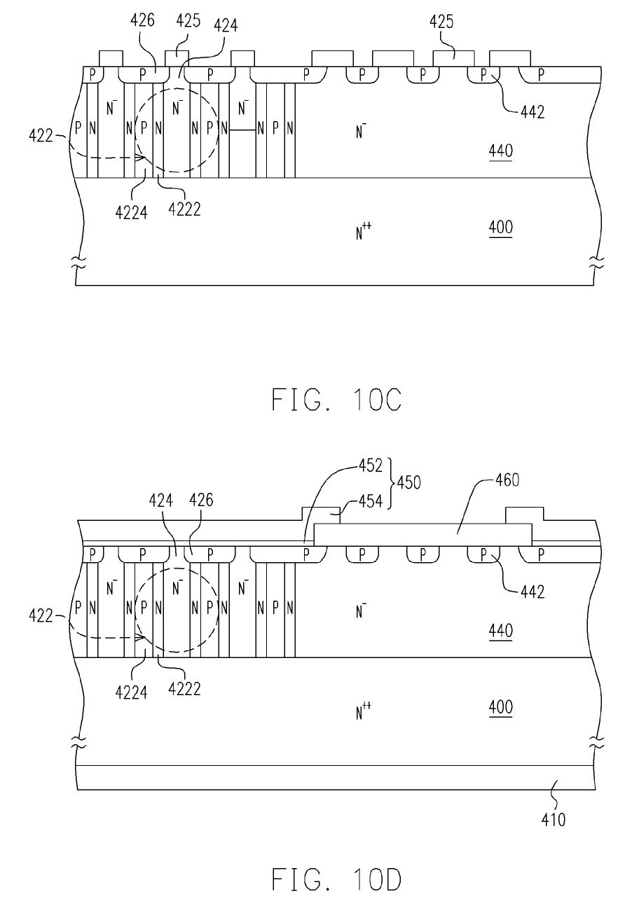

FIGS. 10A-10D illustrates a process flow of fabricating a superjunction Schottky device according to the fourth embodiment of this invention in a cross-sectional view.

Referring to FIG. 10A, an N -doped substrate 400 is provided, and a thin lightly N-doped semiconductor layer 402-1, such as, a thin epitaxial silicon layer, is deposited on the substrate 400. The thickness of the thin semiconductor layer 402-1 is about 1000 Å, for example. N-doped layers 4222-1 and P-doped layers 4224-1 are then formed in the semiconductor layer 402-1 with two ion implantation processes, wherein one P-doped layer 4224-1 is formed between two N-doped layers 4222-1 and one N-doped layer 4222-1 between one unimplanted region 424-1 and one P-doped layer 4224-1. The remaining portion 440-1 of the semiconductor layer 402-1 is a part of the edge termination 440 that will be formed latter.

Referring to FIG. 10B, the above semiconductor layer deposition step and junction forming step are repeated with the N-doped layers and the P-doped layers being aligned with the N-doped layers 4222-1 and P-doped layers 4224-1, respectively. Thereby, the height of the N-doped layers and the P-doped layers is increased step by step. The step cycle is performed until a height required for a predetermined breakdown voltage is obtained, and the unimplanted regions 424 that are still lightly N-doped layers, the N-doped layers 4222 and the P-doped layers 4224 together constitute multiple superjunction cells 422, as shown in FIG. 10C. The lightly N-doped layers 424 also serve as JBS regions. Within each superjunction cell 422, the total number of the P-dopant and that of the N-dopant are made equal to make charge balance, so that the superjunction cell 422 is fully depleted to achieve optimal performance.

Referring to FIG. 10C, a guard-ring mask layer 425 is formed over the lightly N-doped JBS regions 424 and the edge termination 440. Then, a P-type guard ring 426 is formed at the periphery of each JBS region 424 over the corresponding P-doped layers 4224 and N-doped layers 4222, and multiple guard rings 442 are also formed in the top portion of the edge termination 440.

Referring to FIG. 10D, the guard-ring mask layer 425 is removed, and then a blocking layer 460 is formed on the edge termination 440 exposing the JBS regions 424 and the P-type guard rings 426. A front conductor layer 450 is then formed over the substrate 400 using the blocking layer 460 as a mask, contacting with the JBS regions 424 and the P-type guard rings 426. Thereafter, a back metal layer 410 is formed on the back side of the substrate 400.

The Schottky device according to the fifth embodiment can be fabricating by recombining the steps mentioned in the above embodiments with slight modification. Referring to FIG. 5, the superjunction cells 522 and the edge termination 540 can be formed by repeating a semiconductor material deposition step and a junction forming step, as described in the fourth embodiment and illustrated in FIGS. 10A and 10B, while the P-doped layers 5224 and the N-doped layers 5222 are arranged alternately in this embodiment. The lightly-doped JBS regions 524 on the N-doped layers 5222 and the P-type guard rings 526 can be formed with the same method described in the second embodiment.

The Schottky device according to the sixth embodiment can be fabricating by combining some steps mentioned above with a different method for forming the JBS region. Referring to FIG. 6, the superjunction cells 622 and the edge termination 640 can be formed by repeating the same deposition/implantation steps mentioned in the fifth embodiment, while the JBS region 624 can be formed by depositing a lightly N-doped semiconductor layer, such as, an epitaxial silicon layer, overall superjunction cells 622 and the edge termination 640. The P-type guard rings 642 in the edge termination 640 can be formed using the same guard-ring mask layer (325, FIG. 9A) described in the third embodiment.

As mentioned above, in the first to third embodiments of this invention, the superjunction cells can be easily formed by defining trenches and performing ion implantation, wherein only one lithography process is required. While in the fourth to sixth embodiments, the number of required lithography processes is two (for P- and N-implantation) times the number of the thin semiconductor sub-layers. However, since more conducting paths can be provided by omitting isolation structures, the resistance of the Schottky device according to the fourth, fifth or sixth embodiment is lowered.

<Device Operation>

The operation of the Schottky device of this invention is described below with the device of the second embodiment (FIG. 2) as an example. During a period of forward conduction, the electrons flow across the energy barrier between the metal silicide layer 252 and the lightly N-doped JBS region 224, through the JBS region 224, the N-doped layer 2222 of the superjunction cell 222, the substrate 200, and across the ohmic metal contact of the substrate 200. Generally, increasing the barrier height (or the work function of metal) increases the forward resistance, thereby decreasing the forward current conduction. During the biasing process of the Schottky device, there is no minority carrier injection (i.e. holes) into the lightly N-doped JBS region 224 as one would see with a PN junction. The threshold voltage is lower for the Schottky device as compared with a PN junction, and the majority of the current flow is therefore through the JBS region 224.

Under a reverse bias, the net electron flow through the device is small and considered negligible conditions when the applied voltage is much lower than the breakdown voltage of the device. As the breakdown point is approached, however, the current increases dramatically. Because the junction between the P-doped guard ring 226 and the JBS region 224 and the Schottky contact are parallel diodes and the P-doped guard ring 226 will breakdown and punch through prior to the Schottky contact, most of the current load generated once the maximum breakdown voltage has been achieved can be shared by the P-doped guard ring 226.

Referring to FIG. 2 again, there are essentially two diodes, i.e., the junction between the P-doped guard ring 226 and the JBS region 224 and the Schottky contact, in parallel that are both in series with the superjunction cell 222. The superjunction cell 222 will reach a breakdown point prior to the P-doped guard ring 226 and the Schottky contact because the superjunction cell 222 is fully depleted. Therefore, the Schottky contact between the JBS region 224 and the front conductor layer 250 can be protected by the superjunction cells 222 once the maximum break-down voltage has been achieved.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A superjunction Schottky device, comprising:
a back metal layer;
a semiconductor substrate of a first conductivity type on the back metal layer;
a plurality of superjunction cells on the semiconductor substrate, including a plurality of charge-balance layers that extend substantially vertically;
a lightly-doped junction barrier Schottky (JBS) region of the first conductivity type on each superjunction cell; and
a front conductor layer over the substrate, contacting with the JBS region to form a Schottky contact with the IBS region.

2. The superjunction Schottky device of claim 1, further comprising a plurality of isolation structures, wherein each isolation structure is between two superjunction cells and between two JBS regions.

3. The superjunction Schottky device of claim 2, wherein each isolation structure comprises a material selected from the group consisting of doped and undoped oxide, nitride and polysilicon, and combinations thereof.

4. The superjunction Schottky device of claim 2, wherein each superjunction cell comprises a first layer of a second conductivity type, a second layer of the first conductivity type, a lightly-doped third layer of the first conductivity, a fourth layer of the first conductivity type and a fifth layer of the second conductivity type arranged in sequence.

5. The superjunction Schottky device of claim 4, further comprising a guard ring of the second conductivity type at periphery of each Schottky contact above a superjunction cell.

6. The superjunction Schottky device of claim 5, wherein the JBS region is contiguous with the third layer of the superjunction cell, and the guard ring is over the first, second, fourth and fifth layers of he superjunction cell.

7. The superjunction Schottky device of claim 2, wherein each superjunction cell comprises a first layer of a second conductivity type, a second layer of the first conductivity type and a third layer of the second conductivity type arranged in sequence.

8. The superjunction Schottky device of claim 7, wherein the JBS region is located on the second layer of the superjunction cell, and the first and third layers of the superjunction cell extend upward to periphery of the JBS region.

9. The superjunction Schottky device of claim 8, further comprising a guard ring of the second conductivity type at periphery of each Schottky contact above a superjunction cell.

10. The superjunction Schottky device of claim 1, wherein the superjunction cells are arranged adjacent to each other.

11. The superjunction Schottky device of claim 10, wherein each superjunction cell comprises a first layer of a second conductivity type, a second layer of the first conductivity type, a lightly-doped third layer of the first conductivity, a fourth layer of the first conductivity type and a fifth layer of the second conductivity type arranged in sequence.

12. The superjunction Schottky device of claim 11, further comprising a guard ring of the second conductivity type at periphery of each Schottky contact above a superjunction cell.

13. The superjunction Schottky device of claim 12, wherein the JBS region is contiguous with the third layer of the superjunction cell, and the guard ring is over the first, second, fourth and fifth layers of the superjunction cell.

14. The superjunction Schottky device of claim 10, wherein each superjunction cell comprises a first layer of a second conductivity type, a second layer of the first conductivity type, a third layer of the second conductivity type arranged in sequence.

15. The superjunction Schottky device of claim 14, further comprising a guard ring of the second conductivity type at periphery of each Schottky contact above a superjunction cell.

16. The superjunction Schottky device of claim 15, wherein the JBS region is located on the second layer of the superjunction cell, and the guard ring is over the first and third layers and a portion of the second layer of the superjunction cell.

17. The superjunction Schottky device of claim 14, wherein the JBS region comprises a lightly doped region of the first conductivity type over all superjunction cells.

18. The superjunction Schottky device of claim 1, wherein a doping concentration in the superjunction cells ranges from 1×10¹⁵/cm³ to 1×10¹⁷/cm³.

19. The superjunction Schottky device of claim 1, further comprising an edge termination of the first conductivity type on a peripheral portion of the substrate.

20. The superjunction Schottky device of claim 1, wherein the superjunction cells are located in an epitaxial silicon layer.

21. The superjunction Schottky device of claim 1, wherein the front conductor layer comprises a metal layer forming the Schottky contact with the JBS region.

22. The superjunction Schottky device of claim 1, wherein the front conductor layer comprises a metal silicide layer forming the Schottky contact with the JBS region and a metal layer on the metal silicide layer.

23. The superjunction Schottky device of claim 22, wherein the metal silicide layer contains a metal selected from the group consisting of Au, Pt, Ni, Ti, W, Co, Rh, Pd, Zr, Ta, Cr, Mo and alloys of the above metals with various weight ratios.

24. The superjunction Schottky device of claims 22, wherein the metal layer comprises Al, Al/Si alloy, Al/Si/Cu alloy, Mo/Al alloy, Al/Ni/Au alloy, or Ti/Ni/Ag alloy.

25.-45. (canceled)
